(19) United States
(12) Patent Application Publication
(10) Pub. No.: US 2014/0206188 A1
(43) Pub. Date: Jul. 24, 2014

(54) METHOD OF FORMING A METAL SILICIDE LAYER

(71) Applicant: INDUSTRIAL TECHNOLOGY RESEARCH INSTITUTE, Hsin-Chu (TW)

(72) Inventors: Wen-His Lee, Kaohsiung (TW); Chi-Ting Wu, Tainan (TW)

(73) Assignee: INDUSTRIAL TECHNOLOGY RESEARCH INSTITUTE, Hsin-Chu (TW)

(21) Appl. No.: 13/745,572

(22) Filed: Jan. 18, 2013

(51) Int. Cl. H01L 21/02

(52) U.S. Cl. CPC H01L 21/02697
USPC 438/664

(57) ABSTRACT

A method for forming a metal silicide layer is disclosed. The method includes the steps of: forming a first metal layer with a thickness less than 10 nm on a silicon substrate; forming a second metal layer with a thickness more than 10 nm on the first metal layer; annealing the metal layers and the silicon substrate, so that a part of the second metal layer penetrates through the first metal layer, and both the part of the second metal layer penetrating through the first metal layer and a part of the first metal layer react with the silicon substrate to form the metal silicide layer, while the remaining part of the first and second metal layers form a third metal layer; and removing the third metal layer, so that the metal silicide layer can be formed in the semiconductor substrate.

### TECHNICAL FIELD

The present disclosure relates to the field of semiconductor device manufacturing, and more particularly, to a method of forming a metal silicide layer by using a metal interlayer.

### TECHNICAL BACKGROUND

In the manufacture of semiconductor devices, metal silicide is commonly used to form a good ohmic contact and to increase the effective contact area. Conventionally, the self-aligned silicide processing includes the deposition of a metal that forms intermetallic with silicon, but does not react with silicon oxide or silicon nitride. Common metals employed therein are titanium (Ti), cobalt (Co), and nickel (Ni), to form metal silicide of low resistivity such as TiSi₂, CoSi₂ and NiSi. Of which, NiSi has the lowest contact resistance, but its thermal stability is not good. To improve the thermal stability of NiSi, a capping layer is formed on a NiSi layer. This may cause additional fabrication cost to deposit and then remove the capping layer.

Consequently, it is in need to develop a new fabricating method to form a metal silicide such as NiSi with low resistance, no surface aggregation, and good thermal stability.

### TECHNICAL SUMMARY

According to one aspect of the present disclosure, one embodiment provides a method for forming a metal silicide layer. The method includes the steps of: forming a first metal layer on a semiconductor substrate; forming a second metal layer on the first metal layer; and annealing the first and second metal layers and the semiconductor substrate, so that the metal silicide layer can be formed in the semiconductor substrate.

According to another aspect of the present disclosure, another embodiment provides a method for forming a metal silicide layer. The method includes the steps of:
forming a first metal layer with a thickness less than 10 nm on a silicon substrate;
forming a second metal layer with a thickness more than 10 nm on the first metal layer;
annealing the metal layers and the silicon substrate, so that a part of the second metal layer penetrates through the first metal layer, and both the part of the second metal layer penetrating through the first metal layer and a part of the first metal layer react with the silicon substrate to form the metal silicide layer, while the remaining part of the first and second metal layers form a third metal layer; and removing the third metal layer, so that the metal silicide layer can be formed in the semiconductor substrate.

In the embodiments, the semiconductor substrate may be composed of p-type silicon of crystal orientation (100).

In the embodiment, the first metal layer may include a metal selected from the group consisting of molybdenum (Mo), ruthenium (Ru), titanium (Ti), tantalum (Ta), and zinc (Zn).

In the embodiments, the second metal layer may be composed of nickel (Ni).

In the embodiments, the first metal layer may have a thickness equal to or less than about 5 nm and the second metal layer may have a thickness equal to or more than about 20 nm.

In the embodiments, a rapid thermal anneal (RTA) process at a temperature ramp rate of about 30° C./sec in a temperature range between 500° C. and 700° C. may be employed in the step of annealing the metal layers and the silicon substrate.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The present disclosure will become more fully understood from the detailed description given herein below and the accompanying drawings which are given by way of illustration only, and thus are not limitative of the present disclosure and wherein:

FIG. 1 shows a cross-section diagram of the semiconductor wafer according to the embodiment.

FIG. 2 depicts the semiconductor wafer of FIG. 1 after the formation of the second metal layer according to the embodiment.

FIG. 3 shows the semiconductor wafer of FIG. 2 after the RTA process according to the embodiment.

FIG. 4 depicts the semiconductor wafer of FIG. 3 after the removal of the third metal layer according to the embodiment.

FIG. 5 shows the electrochemical potential of NiSi and various metal materials including Zn, Mo, Ru, Ti and Ta, plotted versus its corrosion current.

FIG. 6 shows a flowchart of a method for forming a metal silicide layer according to an exemplary embodiment.

FIG. 7 shows a flowchart of a method for forming a metal silicide layer according to another exemplary embodiment.

FIG. 8 shows sheet resistances of the fabricated NiSi layers, in which the interlayers thereof are respectively composed of Mo, Ru, Ti, Ta, Zn, and Ni.

FIG. 9 shows SEM pictures of the NiSi layer's surfaces, in which the interlayers thereof are respectively composed of Mo, Ru, Ti, Ta, and Zn.

### DESCRIPTION OF THE EXEMPLARY EMBODIMENTS

For further understanding and recognizing the fulfilled functions and structural characteristics of the disclosure, several exemplary embodiments cooperating with detailed description are presented as the following. Reference will now be made in detail to the preferred embodiments, examples of which are illustrated in the accompanying drawings.

In the following description of the embodiments, it is to be understood that when an element such as a layer (film), region, pattern, or structure is stated as being “on” or “under” another element, it can be “directly” on or under another element or can be “indirectly” formed such that an intervening element is also present. Also, the terms such as “on” or “under” should be understood on the basis of the drawings, and they may be used herein to represent the relationship of one element to another element as illustrated in the figures. It will be understood that this expression is intended to encompass different orientations of the elements in addition to the orientation depicted in the figures, namely, to encompass both “on” and “under”. In addition, although the terms “first”, “second” and “third” are used to describe various elements, these elements should not be limited by the term. Also, unless otherwise defined, all terms are intended to have the same meaning as commonly understood by one of ordinary skill in the art.

Hereinafter, a method of forming a metal silicide layer for semiconductor devices according to an embodiment of the present disclosure is going to be described in detail with reference to the accompanying drawings.

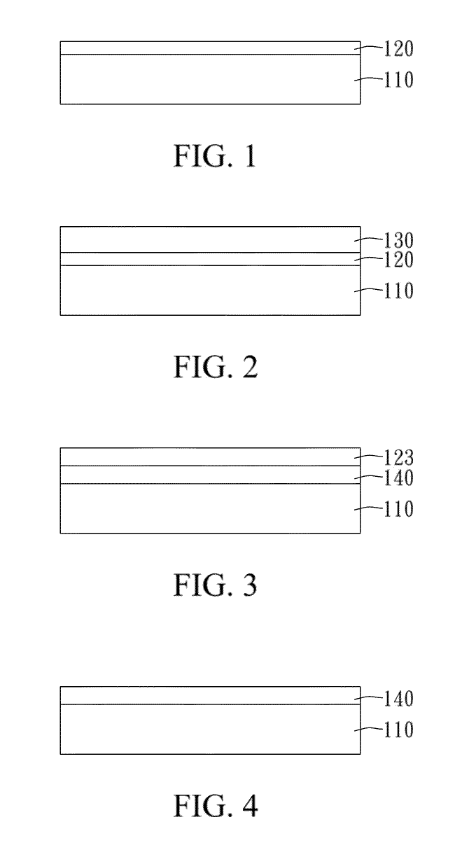

At first, a semiconductor substrate 110 is provided and a first metal layer 120 is then formed on the semiconductor substrate 110, as shown in FIG. 1, which is a cross-section diagram of the semiconductor wafer according to the embodiment. The semiconductor substrate 110 can be a silicon wafer with semiconductor devices formed thereon such as metal-oxide-semiconductor field-effect transistors (MOSFET) and thin-film transistors (TFT). In the embodiment, a p-type Si wafer of crystal orientation (100) is used as the semiconductor substrate 110; but it is not limited thereby, the semiconductor substrate 110 can be of the other semiconductor material. In the embodiment, the first metal layer 120 can be formed of zinc (Zn) by sputtering on the semiconductor substrate 110; but it is not limited thereby, the first metal layer 120 can be of the other metal material such as molybdenum (Mo), ruthenium (Ru), titanium (Ti), and tantalum (Ta). The first metal layer 120 serves as an interlayer between a second metal layer and the Si substrate 110, and its thickness may be less than about 10 nm to facilitate formation of the metal silicide layer of preferable performance in the present disclosure. To deposit a qualified Zn film with a thickness of less than 10 nm, the sputtering process may be performed at a low power, for instance, a sputtering power in the range between 10 and 20 watts.

Next, a second metal layer 130 is formed on the first metal layer 120. FIG. 2 schematically depicts the semiconductor wafer of FIG. 1 after the formation of the second metal layer 130 according to the embodiment. To form a nickel silicide (NiSi) layer on the Si substrate 110 as an example, the second metal layer 130 can be formed of nickel (Ni) with a thickness more than about 10 nm. Preferably, a Ni layer of about 20 nm can be deposited on the first metal layer 120 by sputtering in the embodiment.

To drive atoms of the second metal layer 130 downwards to react with the Si substrate 110 to form the metal silicide layer, an annealing process is performed subsequently. In the embodiment, the Si substrate 110 with the first and second metal layers 120 and 130 are treated by a rapid thermal anneal (RTA) process at a temperature ramp rate of about 30° C./sec in a temperature range between 500° C. and 700° C. for about 30 seconds. Thereby, atoms of the Ni layer 130 can be diffused downwards and penetrate through the Zn layer 120. The Ni atoms can reach the Si substrate 110 to react with the Si atoms therein; thus a NiSi layer (the metal silicide layer) can be formed on the surface of the Si substrate 110. In addition, it should be understood by the skilled person of this field that a part of Zn atoms in the first metal layer 120 may also be diffused downwards during the RTA process to take part in the formation of metal silicide in the embodiment, so that an alloy silicide of NiₓZn₁₋ₓSi may be formed as the metal silicide layer, where NiSi is major while ZnSi is minor in the metal silicide layer. The remaining part of the first and second metal layers may be referred as a third metal layer 123, as shown in FIG. 3, which is the semiconductor wafer of FIG. 2 after the RTA process according to the embodiment. In other words, a large part of the Ni layer 130 may penetrate through the Zn layer 120, and both the part of the Ni layer 130 penetrating through the Zn layer 120 and a part of the Zn layer 120 may react with the Si substrate 110 to form the metal silicide layer, while the remaining part of the Zn and Ni layers 120 and 130 may form the third metal layer 123.

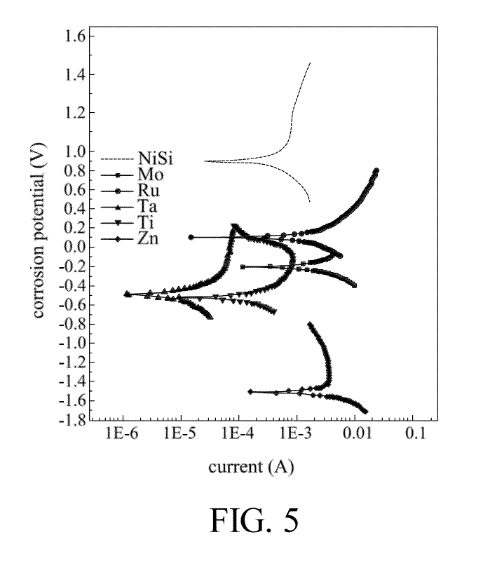

After that, the third metal layer 123 can be removed to expose the metal silicide layer 140, and the semiconductor wafer of FIG. 3 can then be illustrated in FIG. 4 according to the embodiment. Thus, a metal silicide layer 140 can be formed on the semiconductor substrate 110. In the embodiment, removal of the third metal layer 123 can be performed by wet etching, for example, by using an etchant comprising H₂SO₄ and H₂O₂. FIG. 5 shows the electrochemical potentials of NiSi and various metal materials including zinc (Zn), molybdenum (Mo), ruthenium (Ru), titanium (Ti) and tantalum (Ta), plotted versus their corrosion currents. The corrosion potentials are measured in volts (V). A higher corrosion potential means a lower etching rate, so a material of low corrosion potential is subject to be removed in the wet etching. As can be observed in FIG. 5, the corrosion potential of NiSi is higher than those of the metal materials, and Zn has the lowest corrosion potential among those materials. Therefore, the etching rate of the etchant (H₂SO₄+H₂O₂) to etch the third metal layer 123 (of Ni and Zn) is more than that to etch the metal silicide layer 140 (of NiSi or NiₓZn₁₋ₓSO, preventing the metal silicide layer 140 from being etched before the third metal layer 123 is removed. Preferably, the first metal layer 120 of Zn has a thickness in a range between about 5 nm and 10 nm.

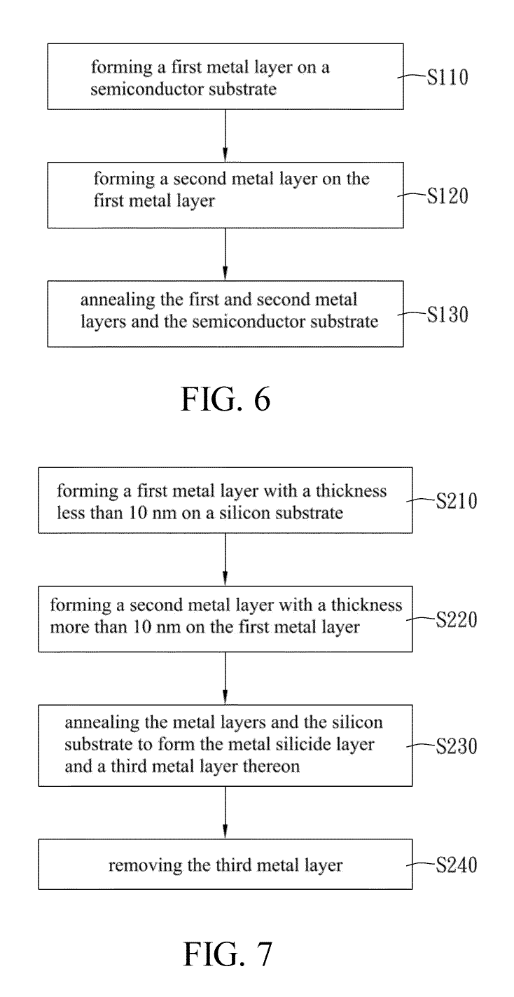

More specifically, FIG. 6 shows a flowchart of a method for forming a metal silicide layer according to an exemplary embodiment. Referring to FIGS. 1 to 4, the method may includes the steps of: forming a first metal layer 120 on a semiconductor substrate 110 (S110); forming a second metal layer 130 on the first metal layer 120 (S120); and annealing the first and second metal layers 120 and 130 and the semiconductor substrate 110 (S130), so that the metal silicide layer can be formed in the semiconductor substrate 110.

On the other aspect, FIG. 7 shows a flowchart of a method for forming a metal silicide layer according to another exemplary embodiment. Referring to FIGS. 1 to 4, the method may includes the steps of: forming a first metal layer 120 with a thickness less than 10 nm on a silicon substrate 110 (S210); forming a second metal layer 130 with a thickness more than 10 nm on the first metal layer 120 (S220); annealing the metal layers 120 and 130 and the silicon substrate 110 (S230) to form the metal silicide layer 140 and a third metal layer 123 thereon, wherein a part of the second metal layer 130 penetrates through the first metal layer 120, and both the part of the second metal layer 130 penetrating through the first metal layer 120 and a part of the first metal layer 120 react with the silicon substrate 110 to form the metal silicide layer 140, while the remaining part of the first and second metal layers form the third metal layer 123; and removing the third metal layer 123 (S240), so that the metal silicide layer 140 can be exposed on the silicon substrate 110.

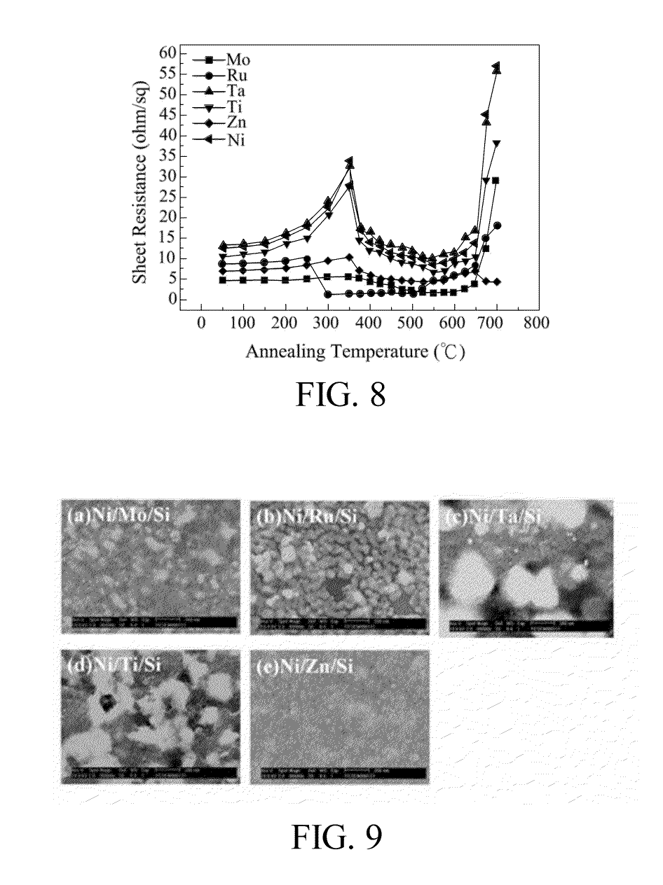

To understand thermal stability of the metal silicide layer, composed of NiSi in the exemplary embodiment, its sheet resistance is then measured versus annealing temperature. FIG. 8 shows sheet resistances of the fabricated NiSi layers, in which the first metal layers or the interlayers thereof are respectively composed of Mo, Ru, Ti, Ta, Zn, and Ni. The less the sheet resistance fluctuates in the range of annealing temperature, the better the NiSi layer's thermal stability is. As shown in FIG. 8, the NiSi layers formed by using barrier metals such as Ta and Ti in the interlayer may have less thermal stability. The barrier metal may prevent the Ni layer from penetrating downward. Also, Zn can be the preferable material for the interlayer, partly because a minor part of Zn atoms in the Zn layer may react with NiSi to form the alloy silicide of NiₓZn₁₋ₓSi during the RTA process, further causing that its sheet resistance may be decreased to less than 10 ohm per square. Thus, contact resistance of the integrated-circuit devices can be further lowed.

To understand surface phenomena of the NiSi layers formed in the exemplary embodiment, FIG. 9 provides scanning electron microscope (SEM) pictures of the NiSi layer's surfaces, in which their interlayers (or the first metal layers) are respectively composed of Mo, Ru, Ti, Ta, and Zn. As shown in FIGS. 9(a) and 9(e), there is no aggregation structure formed on the NiSi layer's surface. This may be because Mo and Zn are not barrier metals, so that Ni atoms in the Ni layer can diffuse downwards smoothly during the RTA process to react with Si atoms in the Si substrate to form the NiSi layer.

As depicted in the foregoing embodiments, a fabricating method of a metal silicide layer for the semiconductor wafer, by using a metal interlayer but not a capping layer, has been demonstrated. Particularly, a nickel silicide (NiSi) has been formed to have low resistance, no surface aggregation, and good thermal stability, which are applicable to interconnection contact layers in the submicron-scaled or nano-scaled semiconductor device manufacturing.

With respect to the above description then, it is to be realized that the optimum dimensional relationships for the parts of the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present disclosure.

What is claimed is:

1. A method of forming a metal silicide layer, comprising the steps of:
forming a first metal layer on a semiconductor substrate;
forming a second metal layer on the first metal layer; and
annealing the first and second metal layers and the semiconductor substrate to form the metal silicide layer in the semiconductor substrate.

2. The method according to claim 1, wherein the first metal layer has a thickness less than 10 nm, the second metal layer has a thickness more than 10 nm.

3. The method according to claim 2, wherein the semiconductor substrate comprises silicon (Si).

4. The method according to claim 2, wherein the first metal layer comprises a metal selected from the group consisting of molybdenum (Mo), ruthenium (Ru), titanium (Ti), tantalum (Ta), and zinc (Zn).

5. The method according to claim 2, wherein the second metal layer comprises nickel (Ni).

6. The method according to claim 5, wherein the first metal layer comprises zinc (Zn).

7. The method according to claim 1, wherein the step of forming the first metal layer is performed by sputtering at an operating power more than about 10 watts and less than about 20 watts, and the first metal layer has a thickness equal to or less than about 5 nm.

8. The method according to claim 1, wherein the step of forming the second metal layer is performed by sputtering, and the second metal layer has a thickness equal to or more than about 20 nm.

9. The method according to claim 1, wherein the step of annealing the metal layers and the semiconductor substrate is performed by a rapid thermal anneal process at a temperature ramp rate of about 30° C./sec in a temperature range between 500° C. and 700° C.

10. A method of forming a metal silicide layer, comprising the steps of:
forming a first metal layer with a thickness less than 10 nm on a silicon substrate;
forming a second metal layer with a thickness more than 10 nm on the first metal layer;
annealing the metal layers and the silicon substrate, so that a part of the second metal layer penetrates through the first metal layer, and both the part of the second metal layer penetrating through the first metal layer and a part of the first metal layer reacting with the silicon substrate to form the metal silicide layer, while the remaining part of the first and second metal layers form a third metal layer; and
removing the third metal layer.

11. The method according to claim 10, wherein the silicon substrate comprises p-type silicon of crystal orientation (100).

12. The method according to claim 10, wherein the first metal layer comprises a metal selected from the group consisting of molybdenum (Mo), ruthenium (Ru), titanium (Ti), tantalum (Ta), and zinc (Zn).

13. The method according to claim 10, wherein the second metal layer comprises nickel (Ni).

14. The method according to claim 13, wherein the first metal layer comprises zinc (Zn).

15. The method according to claim 10, wherein the step of forming the first metal layer is performed by sputtering, and the first metal layer has a thickness equal to or less than about 5 nm.

16. The method according to claim 15, wherein the step of forming the second metal layer is performed by sputtering, and the second metal layer has a thickness equal to or more than about 20 nm.

17. The method according to claim 10, wherein the step of annealing the metal layers and the silicon substrate is performed by a rapid thermal anneal process at a temperature ramp rate of about 30° C./sec in a temperature range between 500° C. and 700° C.

18. The method according to claim 10, wherein the step of removing the third metal layer is performed by using an etchant comprising H₂SO₄ and H₂O₂.
